(19) United States
(12) Patent Application Publication
(10) Pub. No.: US 2026/0169066 A1
(43) Pub. Date: Jun. 18, 2026

(54) TEST DEVICE FOR PERFORMING TEST ON COMBINATIONAL LOGIC CIRCUIT, AND METHOD OF OPERATING THE TEST DEVICE

(71) Applicant: Samsung Electronics Co., Ltd., Suwon-si (KR)

(72) Inventors: Jeongmin LEE, Suwon-si (KR); Jung-Ho SONG, Suwon-si (KR)

(21) Appl. No.: 19/393,127

(22) Filed: Nov. 18, 2025

(30) Foreign Application Priority Data
Dec. 17, 2024 (KR) 10-2024-0189117

(51) Int. Cl. G01R 31/3177; G01R 31/3185

(52) U.S. Cl. CPC G01R 31/3177; G01R 31/318555

(57) ABSTRACT

A test device for testing a combinational logic circuit configured to be in electrical communication with an analog circuit includes a plurality of flip-flops, each of which is connected to the combinational logic circuit; and one or more processors connected to the plurality of flip-flops and configured to test the combinational logic circuit based on a scan signal. The one or more processors are configured to: input an input pattern to the combinational logic circuit through the plurality of flip-flops; obtain a first output value output from a first output node of the combinational logic circuit; determine whether a short current occurs in the analog circuit, by inputting the first output value into the analog circuit; and connect a first cell circuit corresponding to the first output value between the first output node and the analog circuit based on a determination that the short current does not occur.

### CROSS-REFERENCE TO RELATED APPLICATIONS

This application claims priority under 35 U.S.C. § 119 to Korean Patent Application No. 10-2024-0189117 filed on December 17, 2024, in the Korean Intellectual Property Office, the disclosures of which are incorporated by reference herein in their entireties.

### BACKGROUND

With the development of electronics industries, the demands on the characteristics of semiconductor devices are increasing. For example, there is an increasing demand for high reliability, high speed, and/or multi-functionality in semiconductor devices. To satisfy these required characteristics, structures in semiconductor devices are becoming increasingly complex, and semiconductor devices are becoming increasingly highly integrated.

With the increasing integration of semiconductor devices, testing the semiconductor devices takes a lot of time and resources. Design for Testability (DFT) technologies may be used to maintain the quality of semiconductor devices and improve test efficiency.

### SUMMARY

Implementations of the present disclosure described herein relate to a test device for testing a combinational logic circuit, and an operating method of the test device.

Aspects of the present disclosure provide a test device that can reduce the circuit area that may be required to reduce the impact of testing a combinational logic circuit on an analog circuit.

According to an implementation, a test device for testing a combinational logic circuit configured to be in electrical communication with an analog circuit includes a plurality of flip-flops, each of which is connected to the combinational logic circuit; and one or more processors connected to the plurality of flip-flops and configured to test the combinational logic circuit based on a scan signal, wherein the one or more processors are configured to: input an input pattern to the combinational logic circuit through the plurality of flip-flops; obtain a first output value output from a first output node of the combinational logic circuit; determine whether a short current occurs in the analog circuit, by inputting the first output value into the analog circuit; and connect a first cell circuit corresponding to the first output value between the first output node and the analog circuit based on a determination that the short current does not occur, and wherein the first cell circuit comprises at least one logic element and is configured to output the first output value based on the scan signal.

According to an implementation, a method of operating a test device for performing a scan test on a combinational logic circuit configured to be in electrical communication with an analog circuit includes inputting an input pattern to the combinational logic circuit; obtaining a first output value output from a first output node of the combinational logic circuit; determining whether a short current occurs in the analog circuit, by inputting the first output value into the analog circuit; and connecting a first cell circuit corresponding to the first output value between the first output node and the analog circuit based on a determination that the short current does not occur in the analog circuit, wherein the first cell circuit is configured to output the first output value based on a scan signal.

According to an implementation, an integrated circuit includes a combinational logic circuit; an analog circuit configured to be in electrical communication with one or more output nodes of the combinational logic circuit, wherein the one or more output nodes of the combinational logic circuit comprise a first output node; and a test device configured to test the combinational logic circuit based on a scan signal, wherein the test device is configured to: input an input pattern to the combinational logic circuit; obtain a first output value output from the first output node of the combinational logic circuit; determine whether a short current occurs in the analog circuit, by inputting the first output value into the analog circuit; and connect a first cell circuit corresponding to the first output value between the first output node and the analog circuit based on a determination that the short current does not occur, wherein the first cell circuit comprises at least one logic element and is configured to output the first output value based on the scan signal.

### BRIEF DESCRIPTION OF THE FIGURES

The above and other objects and features of the present disclosure will become apparent by describing in detail implementations thereof with reference to the accompanying drawings.

FIG. 1A is a block diagram illustrating an integrated circuit, according to an implementation of the present disclosure.

FIG. 1B is a circuit diagram showing an integrated circuit, according to an implementation.

FIG. 2 is a circuit diagram showing a first cell circuit when a first output value is “0”, according to an implementation.

FIG. 3 is a circuit diagram showing a first cell circuit when a first output value is “0”, according to another implementation.

FIG. 4 is a circuit diagram showing a first cell circuit when a first output value is “1”, according to an implementation.

FIG. 5A is a block diagram illustrating an integrated circuit, according to an implementation.

FIG. 5B is a circuit diagram showing a second cell circuit, according to an implementation.

FIG. 5C is a circuit diagram showing a second cell circuit, according to another implementation.

FIG. 6 is a block diagram illustrating an integrated circuit including a test device further including a random pattern generation circuit, according to an implementation.

FIG. 7 illustrates a configuration of a test device that generates a first cell circuit by using a standard cell library, according to an implementation.

FIG. 8 is a flowchart showing an operating method of a test device, according to an implementation.

FIG. 9 is a flowchart illustrating a method for generating a first cell circuit by using a standard cell library, according to an implementation.

FIG. 10 is a flowchart illustrating a method for detecting an error in a combinational logic circuit by using a random input pattern, according to an implementation.

FIG. 11 is a flowchart illustrating a method for connecting a second cell circuit to a second output node, according to an implementation.

### DETAILED DESCRIPTION

Hereinafter, implementations of the present disclosure will be described in detail and clearly to such an extent that an ordinary one in the art easily implements the present disclosure.

In the present disclosure, expressions such as “first,” “second,” and the like may refer to various components regardless of order and/or importance, and are only used to distinguish one component from another and do not limit the order or importance of the components.

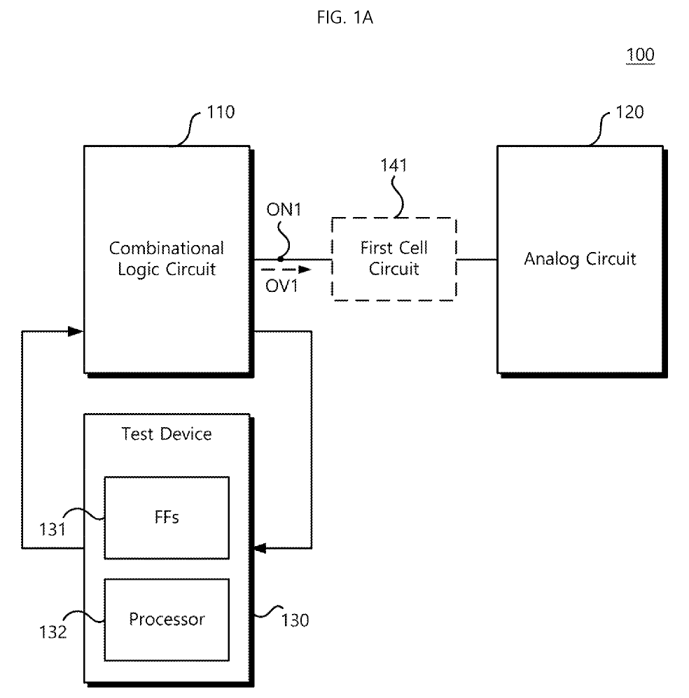

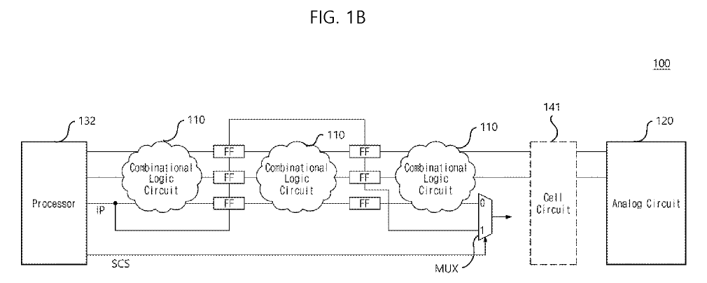

FIG. 1A is a block diagram illustrating an integrated circuit, according to an implementation of the present disclosure. FIG. 1B is a circuit diagram showing an integrated circuit, according to an implementation.

Referring to FIG. 1A, an integrated circuit 100 according to an implementation may include a combinational logic circuit 110, an analog circuit 120, and a test device 130. Moreover, the integrated circuit 100 may further include a first cell circuit 141 connected between the combinational logic circuit 110 and the analog circuit 120.

The integrated circuit 100 may include the combinational logic circuit 110 configured to perform a specified operation.

In more detail, the combinational logic circuit 110 may include at least one logic element. Moreover, the combinational logic circuit 110 may output the result of an operation through at least one logic element in response to data input from the outside.

Furthermore, the integrated circuit 100 may include the analog circuit 120 connected to the combinational logic circuit 110.

In more detail, the integrated circuit 100 may include the analog circuit 120 that performs a specified operation by using at least one analog signal (e.g., a voltage).

According to an implementation, the analog circuit 120 may receive a signal output from the combinational logic circuit 110. For example, the analog circuit 120 may perform a specified operation by using the at least one analog signal and the signal output from the combinational logic circuit 110. For example, the analog circuit 120 may output a power supply voltage or a ground voltage based on signals output from the combinational logic circuit 110.

Also, the integrated circuit 100 may include the test device 130 for testing an operation of the combinational logic circuit 110.

In more detail, the integrated circuit 100 may include the test device 130 that tests whether each of the plurality of nodes included in the combinational logic circuit 110 outputs a value corresponding to an input.

According to an implementation, the test device 130 may include a plurality of flip-flops 131.

In more detail, referring to FIG. 1B, the test device 130 may include the plurality of flip-flops 131 connected to each of a plurality of nodes of the combinational logic circuit 110. Here, the plurality of flip-flops 131 may be connected in series with each other.

In some implementation, the test device 130 may include a processor 132 that controls a test operation for the combinational logic circuit 110 by using the plurality of flip-flops 131.

For example, the processor 132 may execute software (or a program) to control at least one other component (e.g., the plurality of flip-flops 131) of the test device 130 and may process and calculate various types of data. The processor 132 may include a central processing device or microprocessor, and may control the overall operation of the test device 130. Accordingly, the operations performed by the test device 130 may be understood as being performed under the control of the processor 132.

According to an implementation, the processor 132 may perform a test operation (or a scan test operation) on at least part of a plurality of nodes of the combinational logic circuit 110 by using the plurality of flip-flops 131.

In more detail, referring to FIG. 1B, the processor 132 may input an input pattern IP to at least part of the plurality of nodes of the combinational logic circuit 110 through at least part of the plurality of flip-flops 131 in response to a scan signal SCS.

Moreover, the plurality of flip-flops 131 may store data output from each of the plurality of nodes of the combinational logic circuit 110.

Furthermore, the processor 132 may determine, based on data stored in the plurality of flip-flops 131, whether an error occurs in at least part of the plurality of nodes of the combinational logic circuit 110.

For example, the processor 132 may input the scan signal SCS to a multiplexer MUX connected to the plurality of flip-flops 131, and then may output data stored in the plurality of flip-flops 131.

Furthermore, the processor 132 may determine, based on data output from the multiplexer MUX, whether an error occurs in at least part of the plurality of nodes of the combinational logic circuit 110.

For example, the processor 132 may perform a test operation to determine whether an error has occurred in the combinational logic circuit 110 by using the plurality of flip-flops 131. Here, the test operation performed by the processor 132 on the combinational logic circuit 110 may be referred to as a “DFT scan test”.

Besides, the processor 132 may generate the first cell circuit 141 to connect between the combinational logic circuit 110 and the analog circuit 120.

Referring to FIGS. 1A and 1B together, the processor 132 according to an implementation may input the input pattern IP to the combinational logic circuit 110 by using the plurality of flip-flops 131.

Here, the processor 132 may obtain a signal output from a first output node ON1 of the combinational logic circuit 110. For example, the processor 132 may obtain a first output value OV1 of a signal output from the first output node ON1 of the combinational logic circuit 110.

Moreover, the processor 132 may input the first output value OV1 to the analog circuit 120. In more detail, the processor 132 may determine whether a short current occurs in the analog circuit 120 by inputting the first output value OV1 to the analog circuit 120.

When no short current occurs in response to the first output value OV1 in the analog circuit 120, the processor 132 may generate the first cell circuit 141 corresponding to the first output value OV1.

For example, when the first output value OV1 is “1”, the processor 132 may generate the first cell circuit 141 that is preset to correspond to “1”. For another example, when the first output value OV1 is “0”, the processor 132 may generate the first cell circuit 141 that is preset to correspond to “0”.

Furthermore, the processor 132 may connect the first cell circuit 141 between the combinational logic circuit 110 and the analog circuit 120. In more detail, the processor 132 may connect the first cell circuit 141 between the first output node ON1 of the combinational logic circuit 110 and the analog circuit 120.

Here, the first cell circuit 141 may be composed of at least one logic element. For example, the first cell circuit 141 may include at least two or more logic elements, each of which receives a signal output from the first output node ON1 and/or the scan signal SCS.

In some implementation, the first cell circuit 141 may output the first output value OV1 in response to the scan signal SCS.

In more detail, the first cell circuit 141 may output the first output value OV1 in response to the scan signal SCS, regardless of the signal output from the first output node ON1.

In other words, the first cell circuit 141 may reduce the impact of the signal output through the first output node ON1 on the analog circuit 120 depending on a test operation for the combinational logic circuit 110.

For example, the first cell circuit 141 may reduce the number of times that a short current occurs in the analog circuit 120 due to the signal output through the first output node ON1, depending on a test operation for the combinational logic circuit 110.

Referring to the above-described configurations, the processor 132 according to an implementation may identify a value of a signal, which does not cause a short current in the analog circuit 120, from among signals that are output from the output node of the combinational logic circuit 110 and then input to the analog circuit 120.

Furthermore, the processor 132 may generate a cell circuit (e.g., the first cell circuit 141) corresponding to the identified value of the signal and may connect the cell circuit between an output node (e.g., the first output node ON1) of the combinational logic circuit 110 and the analog circuit 120.

In this way, the processor 132 may reduce the number of times that a short current occurs in the analog circuit 120 due to a test operation for the combinational logic circuit 110.

Here, the cell circuit may be composed of at least one logic element. For example, the cell circuit may consist of an inverter and a NOR gate that are connected to each other. For example, the cell circuit according to an implementation of the present disclosure may be understood as a combinational circuit.

Accordingly, the cell circuit according to an implementation of the present disclosure may be implemented in a relatively small area compared to a case where at least one flip-flop and a multiplexer are included. Moreover, the test device 130 according to an implementation may include the relatively small number of data pins compared to a case where the test device includes a data pin for controlling at least one flip-flop.

Through the above-described configurations, the integrated circuit 100 (or the test device 130) according to an implementation of the present disclosure may reduce the circuit area required to reduce the impact of the test for the combinational logic circuit 110 on the analog circuit 120.

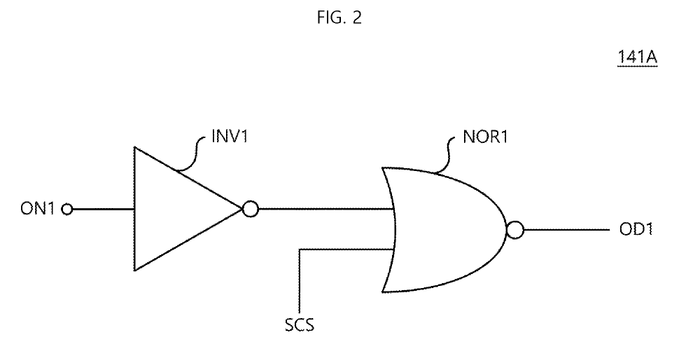

FIG. 2 is a circuit diagram showing a first cell circuit when a first output value is “0”, according to an implementation.

Referring to FIG. 2, a first cell circuit 141A according to an implementation may include a first inverter INV1 and a first NOR gate NOR1.

In more detail, referring to FIGS. 1A and 2 together, when the first output value OV1 is “0”, the processor 132 may generate the first cell circuit 141A that outputs “0” in response to the scan signal SCS.

In an implementation, when the first output value OV1 is “0”, the first cell circuit 141A may include the first inverter INV1 receiving a signal output from the first output node ON1.

Here, the first inverter INV1 may invert and output the signal output from the first output node ON1. For example, when the value of the signal output from the first output node ON1 is “1”, the first inverter INV1 may output a signal whose value is “0”. For another example, when the value of the signal output from the first output node ON1 is “0”, the first inverter INV1 may output a signal whose value is “1”.

Moreover, the first cell circuit 141A may include the first NOR gate NOR1, which performs a NOR operation between the signal output from the first inverter INV1 and the scan signal SCS.

The first NOR gate NOR1 may output a first output data OD1 by performing a NOR operation between the signal output from the first inverter INV1 and the scan signal SCS.

Here, when the value of the scan signal SCS is “1”, the first NOR gate NOR1 may output the first output data OD1, whose value is “0”, regardless of the value of the signal output from the first inverter INV1.

For example, when the scan signal SCS with a value of “1” is input as the test operation for the combinational logic circuit 110 is performed, the first cell circuit 141A may output the first output data OD1 having a value of “0” regardless of the signal output from the first output node ON1.

Furthermore, the processor 132 may connect the first cell circuit 141A between the combinational logic circuit 110 and the analog circuit 120. In more detail, the processor 132 may connect the first cell circuit 141A between the first output node ON1 of the combinational logic circuit 110 and the analog circuit 120.

Accordingly, while the processor 132 performs a test operation on the combinational logic circuit 110, the signal having a value of “0” may be delivered from the first output node ON1 to the analog circuit 120.

Referring to the above-described configurations, the processor 132 according to an implementation may identify the first output value OV1, which is input from the first output node ON1 to the analog circuit 120 and does not cause a short current in the analog circuit 120.

Furthermore, the processor 132 may generate the first cell circuit 141A corresponding to the first output value OV1 and may connect the first cell circuit 141A between the first output node ON1 and the analog circuit 120.

Here, regardless of the value of the signal output from the first output node ON1, the first cell circuit 141A may output the first output data OD1 having the same value as the first output value OV1 during the test operation for the combinational logic circuit 110.

In this way, the processor 132 may reduce the impact of test operations for the combinational logic circuit 110 on the analog circuit 120.

Besides, the first cell circuit 141A may be composed of one inverter and one NOR gate. For example, the first cell circuit 141A according to an implementation of the present disclosure may be implemented in a relatively small area compared to a case where at least one flip-flop and a multiplexer are included.

Moreover, the test device 130 according to an implementation may include the relatively small number of data pins compared to a case where the test device includes a data pin for controlling at least one flip-flop.

Through the above-described configurations, the integrated circuit 100 (or the test device 130) according to an implementation of the present disclosure may reduce the area of a circuit (e.g., the first cell circuit 141A) required to reduce the impact of the test for the combinational logic circuit 110 on the analog circuit 120.

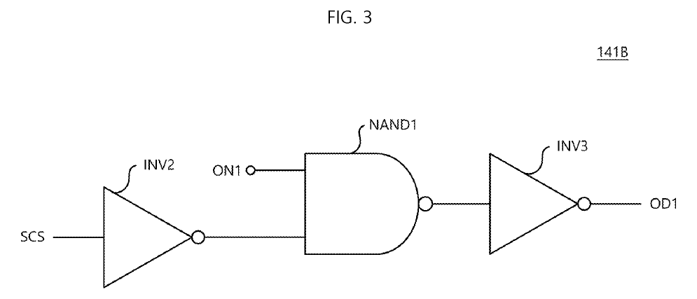

FIG. 3 is a circuit diagram showing a first cell circuit when a first output value is “0”, according to another implementation.

Referring to FIG. 3, a first cell circuit 141B according to an implementation may include a second inverter INV2, a first NAND gate NAND1, and a third inverter INV3.

In more detail, referring to FIGS. 1A and 3 together, when the first output value OV1 is “0” and the electrical length between the combinational logic circuit 110 and the analog circuit 120 is greater than or equal to a threshold value, the processor 132 may generate the first cell circuit 141B that outputs “0” in response to the scan signal SCS.

According to an implementation, the first cell circuit 141B may include the second inverter INV2, the first NAND gate NAND1, and the third inverter INV3, which are connected to each other.

When the first output value OV1 is “0” and the electrical length between the combinational logic circuit 110 and the analog circuit 120 is greater than or equal to the threshold value, the first cell circuit 141B may include the second inverter INV2, which receives the scan signal SCS.

Here, the second inverter INV2 may invert and output the value of the scan signal SCS. For example, when the value of the scan signal SCS is “1”, the second inverter INV2 may output a signal whose value is “0”.

Moreover, the first cell circuit 141B may include the first NAND gate NAND1, which performs a NAND operation between a signal output from the second inverter INV2 and a signal output from the first output node ON1.

Here, for example, when the value of the scan signal SCS is “1”, the first NAND gate NAND1 may output a signal whose value is “1” in response to the second inverter INV2 outputting a signal whose value is “0”.

Furthermore, the first cell circuit 141B may include the third inverter INV3 which receives a signal output from the first NAND gate NAND1.

Here, the third inverter INV3 may invert and output the signal output from the first NAND gate NAND1. For example, when the signal output from the first NAND gate NAND1 is “1”, the third inverter INV3 may output a signal having the value “0”.

For example, when the scan signal SCS with a value of “1” is input as the test operation for the combinational logic circuit 110 is performed, the first cell circuit 141B may output the first output data OD1 having a value of “0” regardless of the value of the signal output from the first output node ON1.

Furthermore, the processor 132 may connect the first cell circuit 141B between the combinational logic circuit 110 and the analog circuit 120. In more detail, the processor 132 may connect the first cell circuit 141B between the first output node ON1 of the combinational logic circuit 110 and the analog circuit 120.

Accordingly, while the processor 132 performs a test operation on the combinational logic circuit 110, the signal having a value of “0” may be delivered from the first output node ON1 to the analog circuit 120.

Referring to the above-described configurations, the processor 132 according to an implementation may identify the first output value OV1, which is input from the first output node ON1 to the analog circuit 120 and does not cause a short current in the analog circuit 120.

Furthermore, the processor 132 may generate the first cell circuit 141B corresponding to the first output value OV1 and may connect the first cell circuit 141A between the first output node ON1 and the analog circuit 120.

Here, regardless of the value of the signal output from the first output node ON1, the first cell circuit 141B may output the first output data OD1 having the same value as the first output value OV1 during the test operation for the combinational logic circuit 110.

In this way, the processor 132 may reduce the impact of test operations for the combinational logic circuit 110 on the analog circuit 120.

Moreover, the first cell circuit 141B may be composed of two inverters and one NAND gate. For example, the first cell circuit 141B according to an implementation of the present disclosure may be implemented in a relatively small area compared to a case where at least one flip-flop and a multiplexer are included.

Moreover, the test device 130 according to an implementation may include the relatively small number of data pins compared to a case where the test device includes a data pin for controlling at least one flip-flop.

Furthermore, according to an implementation, the size of the third inverter INV3 may be proportional to the electrical length between the combinational logic circuit 110 and the analog circuit 120. For example, when the electrical length between the combinational logic circuit 110 and the analog circuit 120 increases, the size of the third inverter INV3 may increase.

For example, compared to the case where a plurality of inverters connected in series are additionally provided as the electrical length between the combinational logic circuit 110 and the analog circuit 120 increases, the first cell circuit 141B according to an implementation of the present disclosure may be implemented in a relatively small area.

Through the above-described configurations, the integrated circuit 100 (or the test device 130) according to an implementation of the present disclosure may reduce the area of a circuit (e.g., the first cell circuit 141B) required to reduce the impact of the test for the combinational logic circuit 110 on the analog circuit 120.

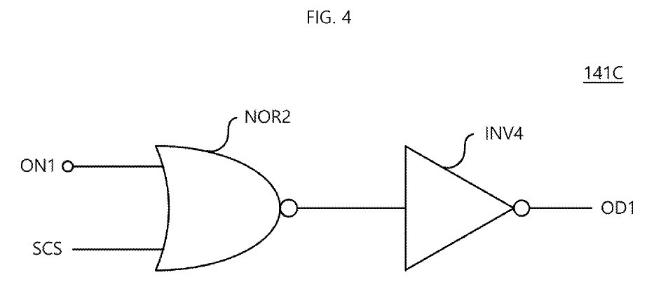

FIG. 4 is a circuit diagram showing a first cell circuit when a first output value is “1”, according to an implementation.

Referring to FIG. 4, a first cell circuit 141C according to an implementation may include a second NOR gate NOR2 and a fourth inverter INV4.

In more detail, referring to FIGS. 1A and 4 together, when the first output value OV1 is “1”, the processor 132 may generate the first cell circuit 141C that outputs “1” in response to the scan signal SCS.

According to an implementation, the first cell circuit 141C may include the second NOR gate NOR2 and the fourth inverter INV4 connected to each other.

When the first output value OV1 is “1”, the first cell circuit 141C may include the second NOR gate NOR2 that performs a NOR operation between the signal output from the first output node ON1 and the scan signal SCS.

Here, for example, when the value of the scan signal SCS is “1”, the second NOR gate NOR2 may output a signal whose value is “0” regardless of the value of the signal output from the first output node ON1.

Also, the first cell circuit 141C may include the fourth inverter INV4 which receives a signal output from the second NOR gate NOR2.

Here, the fourth inverter INV4 may invert and output the signal output from the second NOR gate NOR2. For example, when the signal output from the second NOR gate NOR2 is “0”, the fourth inverter INV4 may output the first output data OD1 whose value is “1”.

For example, when the scan signal SCS with a value of “1” is input as the test operation for the combinational logic circuit 110 is performed, the first cell circuit 141C may output the first output data OD1 having a value of “1” regardless of the value of the signal output from the first output node ON1.

Furthermore, the processor 132 may connect the first cell circuit 141C between the combinational logic circuit 110 and the analog circuit 120. In more detail, the processor 132 may connect the first cell circuit 141C between the first output node ON1 of the combinational logic circuit 110 and the analog circuit 120.

Accordingly, while the processor 132 performs a test operation on the combinational logic circuit 110, the signal having a value of “1” may be delivered from the first output node ON1 to the analog circuit 120.

Referring to the above-described configurations, the processor 132 according to an implementation may identify the first output value OV1, which is input from the first output node ON1 to the analog circuit 120 and does not cause a short current in the analog circuit 120.

Furthermore, the processor 132 may generate the first cell circuit 141C corresponding to the first output value OV1 and may connect the first cell circuit 141A between the first output node ON1 and the analog circuit 120.

Here, regardless of the value of the signal output from the first output node ON1, the first cell circuit 141C may output the first output data OD1 having the same value as the first output value OV1 during the test operation for the combinational logic circuit 110.

In this way, the processor 132 may reduce the impact of test operations for the combinational logic circuit 110 on the analog circuit 120.

Besides, the first cell circuit 141C may be composed of one inverter and one NOR gate. For example, the first cell circuit 141C according to an implementation of the present disclosure may be implemented in a relatively small area compared to a case where at least one flip-flop and a multiplexer are included.

Moreover, the test device 130 according to an implementation may include the relatively small number of data pins compared to a case where the test device includes a data pin for controlling at least one flip-flop.

Through the above-described configurations, the integrated circuit 100 (or the test device 130) according to an implementation of the present disclosure may reduce the area of a circuit (e.g., the first cell circuit 141C) required to reduce the impact of the test for the combinational logic circuit 110 on the analog circuit 120.

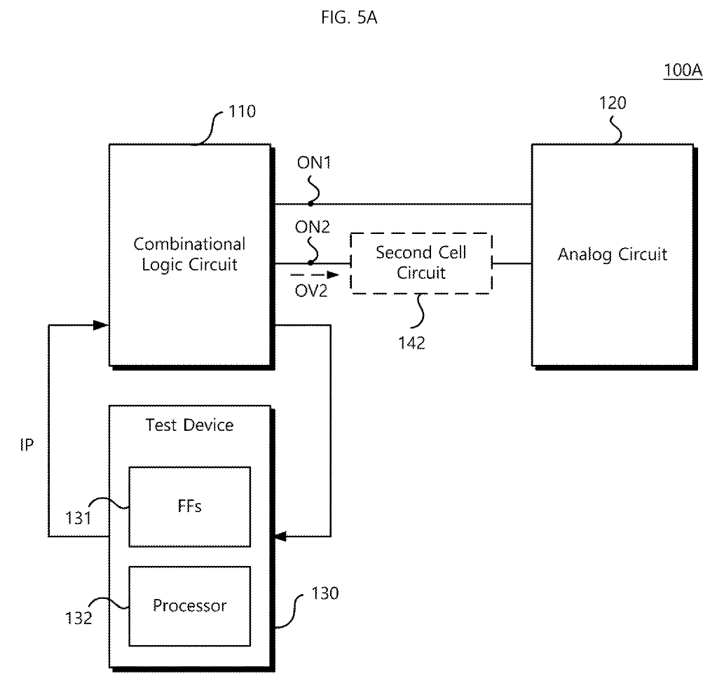

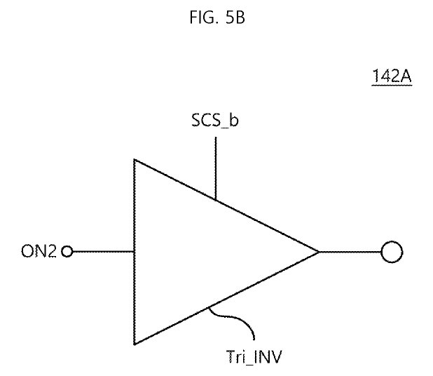

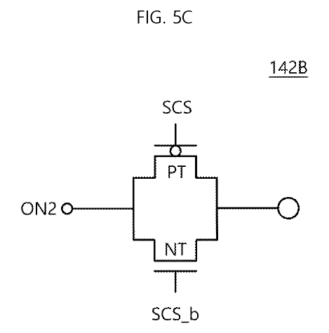

FIG. 5A is a block diagram illustrating an integrated circuit, according to an implementation. FIG. 5B is a circuit diagram showing a second cell circuit, according to an implementation. FIG. 5C is a circuit diagram showing a second cell circuit, according to another implementation.

Referring to FIG. 5A, an integrated circuit 100A according to an implementation may include the combinational logic circuit 110, the analog circuit 120, and the test device 130. Moreover, the integrated circuit 100 may further include a second cell circuit 142 connected between the combinational logic circuit 110 and the analog circuit 120.

Here, the integrated circuit 100A illustrated in FIG. 5A may be understood as an example of the integrated circuit 100 illustrated in FIG. 1A. Accordingly, the same reference numerals are used for components the same or substantially the same as the above-described components, and descriptions the same as the above-described descriptions are omitted to avoid redundancy.

Referring to FIGS. 5A to 5C together, the processor 132 according to an implementation may input the input pattern IP to the combinational logic circuit 110 through the plurality of flip-flops 131.

Also, as the input pattern IP is input to the combinational logic circuit 110, the processor 132 may obtain a second output value OV2 output through a second output node ON2.

Furthermore, the processor 132 may determine whether a short current occurs in the analog circuit 120, based on a change in the second output value OV2 output through the second output node ON2.

Here, the second output value OV2 may have the value of “0” or “1”. Accordingly, the processor 132 may determine whether the short current occurs in the analog circuit 120, based on whether the second output value OV2 changes to “0” or “1”.

For example, when the second output value OV2 has different values as different input patterns are input to the combinational logic circuit 110, the processor 132 may determine whether the short current occurs in the analog circuit 120.

Here, when no short current occurs in the analog circuit 120 regardless of the change in the second output value OV2, the processor 132 may determine that the signal output from the second output node ON2 is independent of whether the short current occurs in the analog circuit 120.

For example, the second output value OV2 output from the second output node ON2 may be input to a configuration other than the analog circuit 120 in the integrated circuit 100.

According to an implementation, when the change in the second output value OV2 does not cause a short current in the analog circuit 120, the processor 132 may generate the second cell circuit 142.

In more detail, when a change in the second output value OV2 does not affect the analog circuit 120, the processor 132 may generate the second cell circuit 142 that opens the second output node ON2.

Referring to FIG. 5B, a second cell circuit 142A according to an implementation may include a tri-phase inverter Tri-INV.

In more detail, the second cell circuit 142A may include the tri-phase inverter Tri-INV that electrically opens the second output node ON2 in response to a reverse-scan signal SCS_b having the reverse phase of the scan signal SCS.

For example, when the reverse-scan signal SCS_b having a value of “0” is input, the tri-phase inverter Tri-INV may electrically open the second output node ON2 regardless of the value of the signal output through the second output node ON2.

Referring to FIG. 5C, a second cell circuit 142B according to another implementation may include at least one pass transistor (PT, NT).

In more detail, the second cell circuit 142B may include the PMOS pass transistor PT and the NMOS pass transistor NT connected to the second output node ON2 in parallel with each other.

Here, the PMOS pass transistor PT may be turned on or off by the scan signal SCS. Moreover, the NMOS pass transistor NT may be turned on or off by the reverse-scan signal SCS_b generated by inverting the scan signal SCS.

For example, when the value of the scan signal SCS is “1” as the processor 132 performs a test operation on the combinational logic circuit 110, the PMOS pass transistor PT and the NMOS pass transistor NT may be turned off.

For example, when the test operation is performed on the combinational logic circuit 110, the second cell circuit 142B may electrically open the second output node ON2 regardless of the value of the signal output from the second output node ON2.

Furthermore, the processor 132 may connect the second cell circuit 142 to the second output node ON2.

In this way, while performing the test operation on the combinational logic circuit 110, the processor 132 may electrically open the second output node ON2.

Referring to the above-described configurations, when a change in the second output value OV2 does not affect the occurrence of a short current in the analog circuit 120, the processor 132 according to an implementation may generate the second cell circuit 142 to electrically open the second output node ON2. Furthermore, the processor 132 may connect the second cell circuit 142 thus generated to the second output node ON2.

Here, the second cell circuit 142 may include the tri-phase inverter Tri-INV or the at least one pass transistor (PT, NT).

For example, the second cell circuit 142 according to an implementation of the present disclosure may be implemented with a relatively small area compared to the case where at least one flip-flop and a multiplexer are included, or a plurality of logic elements connected in series with each other are included.

Through the above-described configurations, the integrated circuit 100A (or the test device 130) according to an implementation of the present disclosure may reduce the area of a circuit (e.g., the second cell circuit 142) required to reduce the impact of the test for the combinational logic circuit 110 on the analog circuit 120.

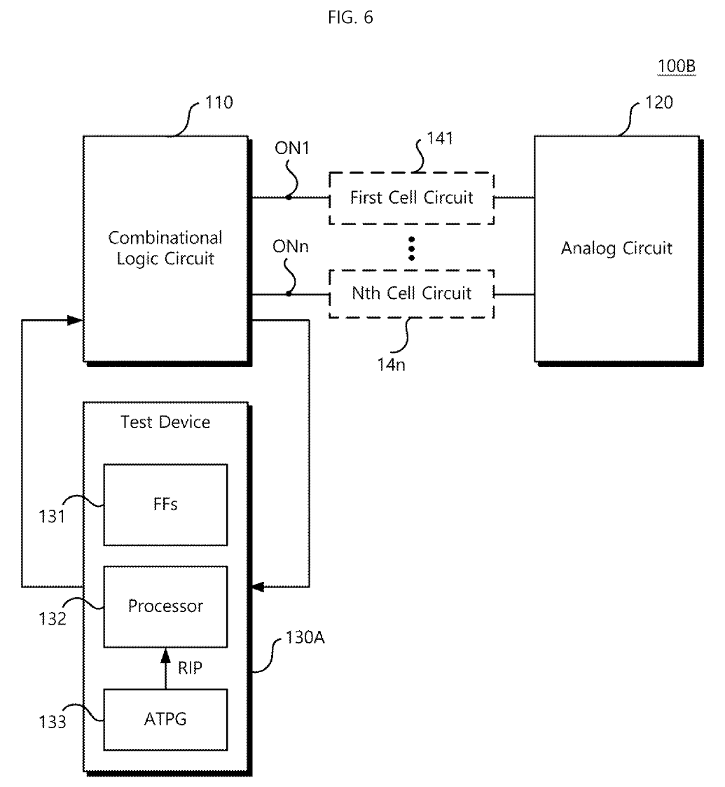

FIG. 6 is a block diagram illustrating an integrated circuit including a test device further including a random pattern generation circuit, according to an implementation.

Referring to FIG. 6, an integrated circuit 100B according to an implementation may include the combinational logic circuit 110, the analog circuit 120, and a test device 130A.

Here, the integrated circuit 100B illustrated in FIG. 6 may be understood as an example of the integrated circuit 100 illustrated in FIG. 1A. Accordingly, the same reference numerals are used for components the same or substantially the same as the above-described components, and descriptions the same as the above-described descriptions are omitted to avoid redundancy.

Referring to FIG. 6, the test device 130A according to an implementation may include the plurality of flip-flops 131, the processor 132, and a random pattern generation circuit 133.

In more detail, the test device 130A may include the random pattern generation circuit 133 connected to the processor 132.

According to an implementation, the random pattern generation circuit 133 may generate a random input pattern RIP.

In more detail, the random pattern generation circuit 133 may generate the random input pattern RIP including a signal to be input for an operation of the combinational logic circuit 110.

Accordingly, the random pattern generation circuit 133 according to an implementation of the present disclosure may be referred to as an “automatic test pattern generation circuit”.

According to an implementation, the processor 132 may input the random input pattern RIP generated from the random pattern generation circuit 133 to the combinational logic circuit 110 through the plurality of flip-flops 131.

Moreover, the processor 132 may obtain a plurality of output values output from each of a plurality of nodes included in the combinational logic circuit 110 in response to the random input pattern RIP.

In more detail, the processor 132 may obtain a plurality of output values output from each of the plurality of nodes included in the combinational logic circuit 110 in response to the random input pattern RIP by using the plurality of flip-flops 131.

Furthermore, the processor 132 may determine whether an error occurs in each of the plurality of nodes of the combinational logic circuit 110.

In more detail, the processor 132 may determine, based on the plurality of output values, whether a value corresponding to the input random input pattern RIP is output from each of the plurality of nodes.

For example, when a value that does not correspond to the random input pattern RIP input is output from at least one of the plurality of nodes, the processor 132 may determine that an error occurs in the corresponding node.

Referring to the above-described configurations, the processor 132 according to an implementation may determine whether an error occurs in each of the plurality of nodes included in the combinational logic circuit 110 by using the random input pattern RIP.

Here, the integrated circuit 100 may include cell circuits 141 to 14n placed between the combinational logic circuit 110 and the analog circuit 120.

For example, while the processor 132 determines whether an error occurs in each node of the combinational logic circuit 110, the impact of the value output from the combinational logic circuit 110 on the analog circuit 120 may be blocked by the plurality of cell circuits 141 to 14n.

While the test operation is performed on the combinational logic circuit 110, the impact of values output from a plurality of output nodes ON1 to ONn of the combinational logic circuit 110 on the analog circuit 120 may be minimized by the plurality of cell circuits 141 to 14n.

Here, each of the plurality of cell circuits 141 to 14n may be composed of at least one logic element. For example, the first cell circuit 141 may consist of an inverter and a NOR gate that are connected to each other.

Accordingly, the first cell circuit 141 according to an implementation of the present disclosure may be implemented in a relatively small area compared to a case where at least one flip-flop and a multiplexer are included.

Moreover, the test device 130 according to an implementation may include the relatively small number of data pins compared to a case where the test device includes a data pin for controlling at least one flip-flop.

Through the above-described configurations, the integrated circuit 100 (or the test device 130) according to an implementation of the present disclosure may reduce the circuit area required to reduce the impact of the test for the combinational logic circuit 110 on the analog circuit 120.

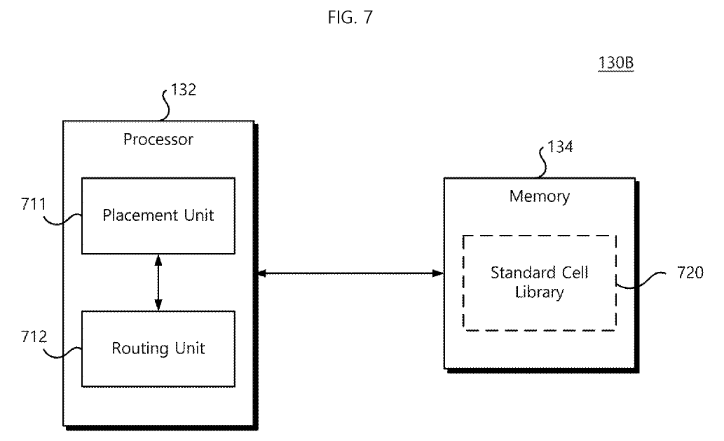

FIG. 7 illustrates a configuration of a test device that generates a first cell circuit by using a standard cell library, according to an implementation.

Referring to FIG. 7, a test device 130B according to an implementation may include the processor 132 and a memory 134.

Here, the test device 130B illustrated in FIG. 7 may be understood as an example of the test device 130 illustrated in FIG. 1. Accordingly, the same reference numerals are used for components the same or substantially the same as the above-described components, and descriptions the same as the above-described descriptions are omitted to avoid redundancy.

The test device 130B according to an implementation may include the memory 134 connected to the processor 132.

The memory 134 may be a computer-readable storage medium, and may include an arbitrary storage medium that stores data and/or instructions executed by a computer. For example, the computer-readable storage medium may include a volatile memory such as a RAM, a ROM, and the like, and a non-volatile memory such as a flash memory, an MRAM, a PRAM, an RRAM, and the like. The computer-readable storage medium may be capable of being inserted in a computer, may be integrated in the computer, or may be coupled with the computer through a communication medium such as a network and/or a wireless link.

According to an implementation, the memory 134 may include a standard cell library 720. The standard cell library 720 may be provided from the memory 134 to the processor 132.

The standard cell library 720 may include a plurality of standard cells. Here, the standard cell may be understood as a unit constituting the minimum unit in the design of a block, an element, or a chip. For example, the standard cell library 720 may include standard cells respectively corresponding to an inverter, a NAND gate, and a NOR gate.

According to an implementation, the processor 132 may include a placement unit 711 and a routing unit 712.

The processor 132 may generate a cell circuit based on input data defining an integrated circuit by using the placement unit 711 and the routing unit 712.

In more detail, the placement unit 711 may place standard cells stored in the standard cell library 720 based on input data defining an integrated circuit.

For example, referring to FIG. 2, the placement unit 711 may place standard cells stored in the standard cell library 720 so as to correspond to an inverter and an NOR gate.

Moreover, the processor 132 may perform signal routing on the placement of standard cells provided from the placement unit 711 by using the routing unit 712.

For example, referring to FIG. 2, the routing unit 712 may route a signal such that a signal output from the first output node ON1 of the combinational logic circuit 110 is input to a standard cell corresponding to the inverter. Furthermore, for example, the routing unit 712 may route a signal such that the output of the inverter and the scan signal SCS are input to the standard cell corresponding to the NOR gate.

Referring to FIG. 7, the placement unit 711 and the routing unit 712 may be implemented as configurations that are separate and distinct, but are not limited thereto. According to another implementation, the placement unit 711 and the routing unit 712 may be implemented as a single integrated configuration.

Also, each of the placement unit 711 and the routing unit 712 may be understood as a circuit formed within the processor 132.

Referring to the above-described configuration, the processor 132 according to an implementation may generate cell circuits respectively connected to output nodes ON1 to ONn of the combinational logic circuit 110 by using standard cells.

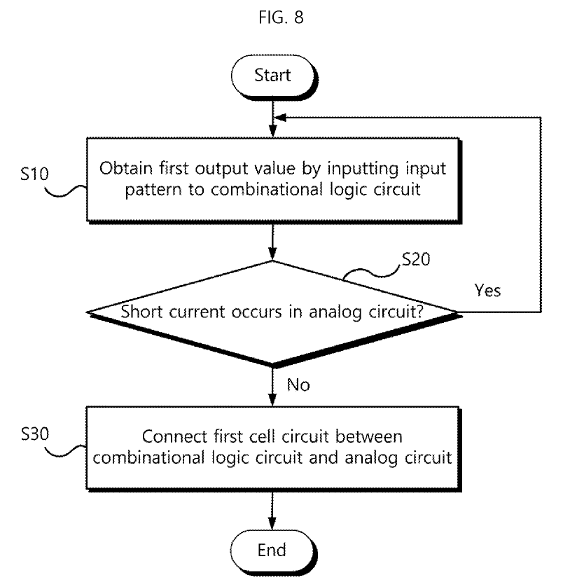

FIG. 8 is a flowchart showing an operating method of a test device, according to an implementation.

Referring to FIG. 8, the test device 130 (or the processor 132) according to an implementation may generate a cell circuit corresponding to a value that does not cause a short current in the analog circuit 120, and may connect the cell circuit to an output node of the combinational logic circuit 110.

In operation S10, the processor 132 according to an implementation may obtain the first output value OV1 from the first output node ON1 by inputting the input pattern IP to the combinational logic circuit 110.

In more detail, the processor 132 may input the input pattern IP to at least part of a plurality of nodes of the combinational logic circuit 110 through at least part of the plurality of flip-flops 131 in response to the scan signal SCS.

Moreover, the processor 132 may obtain the first output value OV1 output from the first output node ON1 of the combinational logic circuit 110.

In operation S20, the processor 132 according to an implementation may determine whether a short current occurs in the analog circuit 120, as the first output value OV1 is input to the analog circuit 120.

In more detail, the processor 132 may input the first output value OV1 to the analog circuit 120. Furthermore, the processor 132 may determine whether a short current occurs in the analog circuit 120 by inputting the first output value OV1 to the analog circuit 120.

When no short current occurs in response to the first output value OV1 in the analog circuit 120, in operation S30, the processor 132 according to an implementation may generate the first cell circuit 141 and may connect the first cell circuit 141 between the combinational logic circuit 110 and the analog circuit 120.

In more detail, when no short current occurs in response to the first output value OV1 in the analog circuit 120, the processor 132 may generate the first cell circuit 141 corresponding to the first output value OV1.

For example, when the first output value OV1 is “1”, the processor 132 may generate the first cell circuit 141 that is preset to correspond to “1”.

For another example, when the first output value OV1 is “0”, the processor 132 may generate the first cell circuit 141 that is preset to correspond to “0”.

Furthermore, the processor 132 may connect the first cell circuit 141 between the combinational logic circuit 110 and the analog circuit 120. In more detail, the processor 132 may connect the first cell circuit 141 between the first output node ON1 of the combinational logic circuit 110 and the analog circuit 120.

Here, the first cell circuit 141 may be composed of at least one logic element. For example, the first cell circuit 141 may include at least two or more logic elements, each of which receives a signal output from the first output node ON1 and/or the scan signal SCS.

In some implementation, the first cell circuit 141 may output the first output value OV1 in response to the scan signal SCS.

In more detail, regardless of the value of the signal output from the first output node ON1, the first cell circuit 141 may output the first output value OV1 in response to the scan signal SCS depending on a test operation of the combinational logic circuit 110.

In other words, the first cell circuit 141 may reduce the impact of the signal output through the first output node ON1 on the analog circuit 120 depending on a test operation for the combinational logic circuit 110.

For example, the first cell circuit 141 may reduce the number of times that a short current occurs in the analog circuit 120 due to the signal output through the first output node ON1, depending on a test operation for the combinational logic circuit 110.

According to another implementation, when the short current occurs in response to the first output value OV1 in the analog circuit 120, the processor 132 may obtain a signal output from the first output node ON1 by inputting an input pattern to the combinational logic circuit 110. For example, when the short current occurs in response to the first output value OV1 in the analog circuit 120, the processor 132 may perform operation S10.

Referring to the above-described configurations, the processor 132 according to an implementation may identify a value of a signal, which does not cause a short current in the analog circuit 120, from among signals that are output from the output node of the combinational logic circuit 110 and then input to the analog circuit 120.

Furthermore, the processor 132 may generate a cell circuit (e.g., the first cell circuit 141) corresponding to the identified value of the signal and may connect the cell circuit between an output node of the combinational logic circuit 110 and the analog circuit 120.

In this way, the processor 132 may reduce the number of times that a short current occurs in the analog circuit 120 due to a test operation for the combinational logic circuit 110.

Here, the cell circuit may be composed of at least one logic element. Accordingly, the first cell circuit 141 according to an implementation of the present disclosure may be implemented in a relatively small area compared to a case where at least one flip-flop and a multiplexer are included.

Moreover, the test device 130 according to an implementation may include the relatively small number of data pins compared to a case where the test device includes a data pin for controlling at least one flip-flop.

Through the above-described configurations, the integrated circuit 100 (or the test device 130) according to an implementation of the present disclosure may reduce the circuit area required to reduce the impact of the test for the combinational logic circuit 110 on the analog circuit 120.

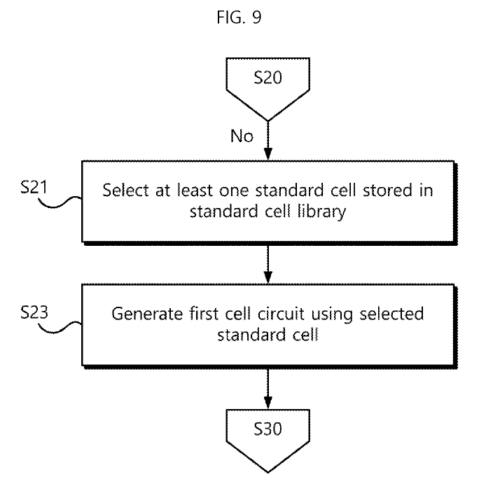

FIG. 9 is a flowchart illustrating a method for generating a first cell circuit by using a standard cell library, according to an implementation.

Referring to FIG. 9, the test device 130 (or the processor 132) according to an implementation may generate the first cell circuit 141 by using a standard cell.

In operation S21, the processor 132 according to an implementation may select at least one standard cell stored in the standard cell library 720.

In more detail, when no short current occurs in the analog circuit 120 in response to the first output value OV1, the processor 132 may receive (or load) input data defining the first cell circuit 141 corresponding to the first output value OV1.

Furthermore, the processor 132 may select standard cells corresponding to logic elements included in the first cell circuit 141 from among standard cells stored in the standard cell library 720 based on input data defining the first cell circuit 141.

In operation S23, the processor 132 according to an implementation may generate the first cell circuit 141 by using the selected standard cell.

In more detail, the processor 132 may place at least one selected standard cell. Furthermore, the processor 132 may perform routing such that a specified signal is input to the placed standard cells.

For example, referring to FIG. 2 together, the processor 132 according to an implementation may place a standard cell corresponding to an inverter and a standard cell corresponding to a NOR gate.

Moreover, the processor 132 may route a signal such that the signal output from the first output node ON1 is input to the standard cell corresponding to the inverter. Furthermore, the processor 132 may route a signal such that the output of the inverter and the scan signal SCS are input to the standard cell corresponding to the NOR gate.

Referring to the above configuration, the processor 132 according to an implementation may generate the first cell circuit 141 connected to the first output node ON1 by using standard cells.

For example, the first cell circuit 141 may be composed of at least one logic element. Accordingly, the first cell circuit 141 according to an implementation of the present disclosure may be implemented in a relatively small area compared to a case where at least one flip-flop and a multiplexer are included.

Through the above-described configurations, the integrated circuit 100 (or the test device 130) according to an implementation of the present disclosure may reduce the circuit area required to reduce the impact of the test for the combinational logic circuit 110 on the analog circuit 120.

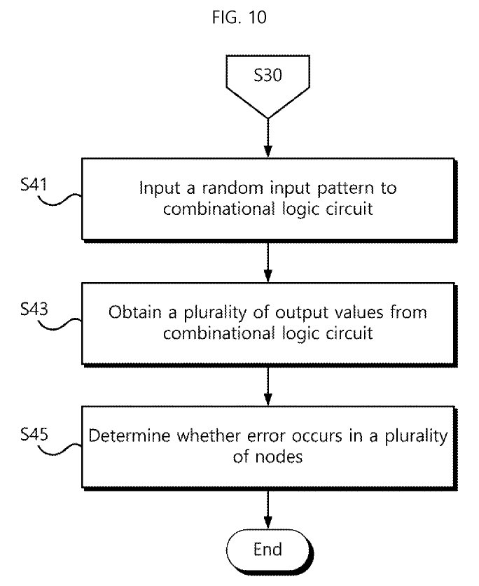

FIG. 10 is a flowchart illustrating a method for detecting an error in a combinational logic circuit by using a random input pattern, according to an implementation.

Referring to FIG. 10, the test device 130 (or the processor 132) according to an implementation may perform a test operation on the combinational logic circuit 110 by inputting the random input pattern RIP into the combinational logic circuit 110.

In more detail, the processor 132 may determine whether the combinational logic circuit 110 operates normally, based on a signal output from each node of the combinational logic circuit 110 as inputting the random input pattern RIP to the combinational logic circuit 110.

In operation S41, the processor 132 according to an implementation may input the random input pattern RIP to the combinational logic circuit 110.

In more detail, the processor 132 may input the random input pattern RIP output from the random pattern generation circuit 133 to the combinational logic circuit 110 through the plurality of flip-flops 131.

In operation S43, the processor 132 according to an implementation may obtain a plurality of output values output from the combinational logic circuit 110.

In more detail, the processor 132 may obtain a plurality of output values respectively output from a plurality of nodes of the combinational logic circuit 110 in response to the random input pattern RIP.

In operation S45, the processor 132 according to an implementation may determine whether an error occurs in each of the plurality of nodes of the combinational logic circuit 110.

In more detail, the processor 132 may determine, based on the plurality of output values, whether a value corresponding to the input random input pattern RIP is output from each of the plurality of nodes.

For example, when a value that does not correspond to the random input pattern RIP input is output from at least one of the plurality of nodes, the processor 132 may determine that an error occurs in the corresponding node.

Referring to the above-described configurations, the processor 132 according to an implementation may determine whether an error occurs in each of the plurality of nodes included in the combinational logic circuit 110 by using the random input pattern RIP.

While operations S41 to S45 are performed, the impact of values respectively output from the plurality of output nodes ON1 to ONn of the combinational logic circuit 110 on the analog circuit 120 may be blocked by the plurality of cell circuits 141 to 14n.

For example, while the test operation is performed on the combinational logic circuit 110, the impact of values output from a plurality of output nodes ON1 to ONn of the combinational logic circuit 110 on the analog circuit 120 may be minimized by the plurality of cell circuits 141 to 14n.

Here, each of the plurality of cell circuits 141 to 14n may be composed of at least one logic element. For example, the first cell circuit 141 may consist of an inverter and a NOR gate that are connected to each other.

Accordingly, the first cell circuit 141 according to an implementation of the present disclosure may be implemented in a relatively small area compared to a case where at least one flip-flop and a multiplexer are included.

Moreover, the test device 130 according to an implementation may include the relatively small number of data pins compared to a case where the test device includes a data pin for controlling at least one flip-flop.

Through the above-described configurations, the integrated circuit 100 (or the test device 130) according to an implementation of the present disclosure may reduce the circuit area required to reduce the impact of the test for the combinational logic circuit 110 on the analog circuit 120.

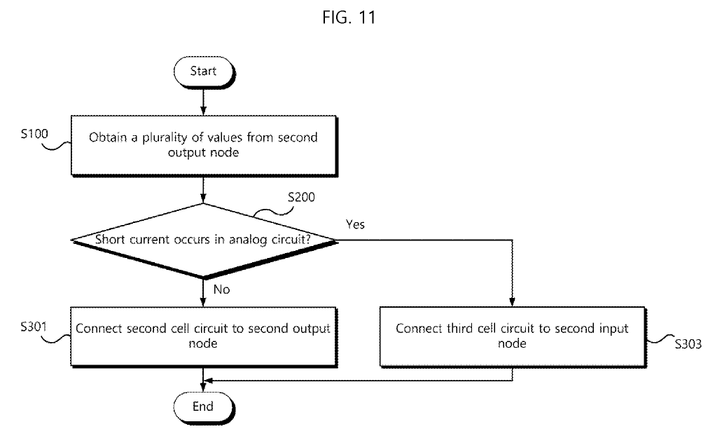

FIG. 11 is a flowchart illustrating a method for connecting a second cell circuit to a second output node, according to an implementation.

Referring to FIG. 11, when a change in the second output value OV2 output through the second output node ON2 does not affect whether a short current occurs in the analog circuit 120, the processor 132 according to an implementation may connect the second cell circuit 142 to the second output node ON2.

In operation S100, the processor 132 according to an implementation may obtain the second output value OV2 output from the second output node ON2.

In more detail, the processor 132 may input an input pattern to the combinational logic circuit 110 through the plurality of flip-flops 131. Also, as the input pattern is input to the combinational logic circuit 110, the processor 132 may obtain the second output value OV2 output through the second output node ON2.

Furthermore, the processor 132 may input a plurality of values output from the second output node ON2 to the analog circuit 120.

Here, the second output value OV2 may have the value of “0” or “1”.

Accordingly, the processor 132 may obtain different output values output to have different values (e.g., “0” or “1”) through the second output node ON2 and may input the different output values to the analog circuit 120.

In operation S200, the processor 132 according to an implementation may determine whether a short current occurs in the analog circuit 120, based on a change in the second output value OV2.

In more detail, the processor 132 may determine whether the short current occurs in the analog circuit 120, based on whether the second output value OV2 changes to “0” or “1”.

For example, when the second output value OV2 has different values as different input patterns are input to the combinational logic circuit 110, the processor 132 may determine whether the short current occurs in the analog circuit 120.

Here, for example, when no short current occurs in the analog circuit 120 regardless of the change in the second output value OV2, the processor 132 may determine that the signal output from the second output node ON2 is independent of whether the short current occurs in the analog circuit 120.

Moreover, for another example, when the short current occurs in the analog circuit 120 regardless of the change in the second output value OV2, the processor 132 may determine that the signal output from the second output node ON2 is independent of whether the short current occurs in the analog circuit 120.

In operation S301, the processor 132 according to an implementation may connect the second cell circuit 142 to the second output node ON2.

In more detail, when the change in the second output value OV2 does not cause a short current in the analog circuit 120, the processor 132 may generate the second cell circuit 142.

When a change in the second output value OV2 does not affect the analog circuit 120, the processor 132 may generate the second cell circuit 142 that opens the second output node ON2.

For example, the processor 132 may generate the second cell circuit 142 including the tri-phase inverter Tri-INV.

Here, the second cell circuit 142 may electrically open the second output node ON2 in response to the reverse-scan signal SCS_b generated by inverting the scan signal SCS.

For example, when the reverse-scan signal SCS_b having a value of “0” is input, the tri-phase inverter Tri-INV may electrically open the second output node ON2 regardless of the value of the signal output through the second output node ON2.

For another example, the processor 132 may generate the second cell circuit 142 including the at least one pass transistor (PT, NT).

In more detail, the second cell circuit 142 may include the PMOS pass transistor PT and the NMOS pass transistor NT connected to the second output node ON2 in parallel with each other.

Here, the PMOS pass transistor PT may be turned on or off by the scan signal SCS. Moreover, the NMOS pass transistor NT may be turned on or off by the reverse-scan signal SCS_b generated by inverting the scan signal SCS.

For example, when the value of the scan signal SCS is “1” as the processor 132 performs a test operation on the combinational logic circuit 110, the PMOS pass transistor PT and the NMOS pass transistor NT may be turned off.

For example, when the test operation is performed on the combinational logic circuit 110, the second cell circuit 142 may electrically open the second output node ON2 regardless of the value of the signal output from the second output node ON2.

Furthermore, the processor 132 may connect the second cell circuit 142 to the second output node ON2.

In this way, while performing the test operation on the combinational logic circuit 110, the processor 132 may electrically open the second output node ON2.

According to another implementation, when a short current occurs in the analog circuit 120, in operation S303, the processor 132 according to an implementation may connect the third cell circuit to the second output node ON2.

In more detail, when a change in the second output value OV2 causes a short current in the analog circuit 120, the processor 132 may identify a value, which does not cause the short current in the analog circuit 120, from among the second output value OV2.

For example, when a short current occurs in the analog circuit 120 as the second output value OV2 changes from “0” to “1”, the processor 132 may determine that the second output value OV2, whose value is “0”, does not cause a short current in the analog circuit 120.

Furthermore, the processor 132 may generate a third cell circuit corresponding to the second output value OV2 (e.g., “0”) that does not generate the short current in the analog circuit 120 and may connect the third cell circuit to the second output node ON2.

In more detail, the processor 132 may connect the third cell circuit corresponding to a value, which does not cause a short current in the analog circuit 120, from among values output from the second output node ON2 between the second output node ON2 and the analog circuit 120.

Referring to the above-described configurations, when a change in the second output value OV2 does not affect the occurrence of a short current in the analog circuit 120, the processor 132 according to an implementation may generate the second cell circuit 142 to electrically open the second output node ON2.

Furthermore, the processor 132 may connect the generated second cell circuit 142 to the second output node ON2.

Here, the second cell circuit 142 may include the tri-phase inverter Tri-INV or the at least one pass transistor (PT, NT).

For example, the second cell circuit 142 according to an implementation of the present disclosure may be implemented with a relatively small area compared to a case where at least one flip-flop and a multiplexer are included, or a case where a plurality of logic elements connected in series with each other are included.

Through the above-described configurations, the integrated circuit 100 (or the test device 130) according to an implementation of the present disclosure may reduce the area of a circuit (e.g., the second cell circuit 142) required to reduce the impact of the test for the combinational logic circuit 110 on the analog circuit 120.

As described above, the processor 132 according to an implementation of the present disclosure may identify a value of a signal, which does not cause a short current in the analog circuit 120, from among signals that are output from the output node of the combinational logic circuit 110 and then input to the analog circuit 120.

Furthermore, the processor 132 may generate a cell circuit (e.g., the first cell circuit 141) corresponding to the identified value of the signal and may connect the cell circuit between an output node of the combinational logic circuit 110 and the analog circuit 120.

In this way, the processor 132 may reduce the impact of the signal output through the first output node ON1 on the analog circuit 120 depending on a test operation for the combinational logic circuit 110.

Here, the cell circuit may be composed of at least one logic element. Accordingly, the first cell circuit 141 according to an implementation of the present disclosure may be implemented in a relatively small area compared to a case where at least one flip-flop and a multiplexer are included.

Moreover, the test device 130 according to an implementation may include the relatively small number of data pins compared to a case where the test device includes a data pin for controlling at least one flip-flop.

Through the above-described configurations, the integrated circuit 100 (or the test device 130) according to an implementation of the present disclosure may reduce the circuit area required to reduce the impact of the test for the combinational logic circuit 110 on the analog circuit 120.

Implementations in which a design is changed simply or which are easily changed may be included in the present disclosure as well as an implementation described above. In addition, technologies that are easily changed and implemented by using the above implementations may be included in the present disclosure. Accordingly, it will be apparent to those of ordinary skill in the art that various changes and modifications may be made to the above implementations without departing from the spirit and scope of the present disclosure as set forth in the following claims.

According to an implementation of the present disclosure, a test device may reduce the circuit area required to reduce the impact of testing a combinational logic circuit on an analog circuit.

In some implementations, the processor (e.g., processor 132) discussed in the present disclosure may include one or more processors. In some implementations, all of the functions of the processor may be performed by a single processor. In other implementations, the functions of the processor may be distributed among multiple processors (e.g., one processor performs a subset of the functions of the processor 132 while one or more other processors perform the remaining functions of the processor 132.)

While the present disclosure contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the present disclosure has been described with reference to implementations thereof, it will be apparent to those of ordinary skill in the art that various changes and modifications may be made thereto without departing from the spirit and scope of the present disclosure as set forth in the following claims.

What is claimed is:

1. A test device for testing a combinational logic circuit configured to be in electrical communication with an analog circuit, the test device comprising:
a plurality of flip-flops, each of which is connected to the combinational logic circuit; and
one or more processors connected to the plurality of flip-flops and configured to test the combinational logic circuit based on a scan signal,
wherein the one or more processors are configured to:
input an input pattern to the combinational logic circuit through the plurality of flip-flops;
obtain a first output value output from a first output node of the combinational logic circuit;
determine whether a short current occurs in the analog circuit, by inputting the first output value into the analog circuit; and
connect a first cell circuit corresponding to the first output value between the first output node and the analog circuit based on a determination that the short current does not occur, and
wherein the first cell circuit comprises at least one logic element and is configured to output the first output value based on the scan signal.

2. The test device of claim 1, wherein based on the first output value being “0”, the first cell circuit includes:
a first inverter configured to receive the first output value from the first output node; and
a first NOR gate configured to perform a NOR operation based on an output of the first inverter and the scan signal.

3. The test device of claim 1, wherein based on the first output value being “0” and an electrical length between the combinational logic circuit and the analog circuit being greater than or equal to a predetermined threshold value, the first cell circuit includes:
a second inverter configured to receive the scan signal;
a first NAND gate configured to perform a NAND operation based on the first output value from the first output node and an output of the second inverter; and
a third inverter configured to receive an output of the first NAND gate,
wherein a size of the third inverter is proportional to the electrical length between the combinational logic circuit and the analog circuit.

4. The test device of claim 1, wherein based on the first output value being “1”, the first cell circuit includes:
a second NOR gate configured to perform a NOR operation based on the first output value from the first output node and the scan signal; and
a fourth inverter configured to receive an output of the second NOR gate.

5. The test device of claim 1, wherein the one or more processors are configured to:
input different output values output from a second output node of the combinational logic circuit to the analog circuit based on the input pattern; and
connect a second cell circuit to the second output node based on the determination that the short current does not occur in the analog circuit by inputting the different output values to the analog circuit,
wherein the second cell circuit is configured to electrically open the second output node based on the scan signal.

6. The test device of claim 5, wherein the second cell circuit includes a tri-phase inverter that is configured to electrically open the second output node based on a signal having a reverse phase of the scan signal.

7. The test device of claim 5, wherein the second cell circuit includes at least one pass transistor configured to electrically open the second output node based on the scan signal.

8. The test device of claim 1, wherein the one or more processors are configured to:
select at least one standard cell, from among standard cells stored in a standard cell library, corresponding to the at least one logic element based on the first output value, based on the determination that the short current does not occur in the analog circuit; and
generate the first cell circuit by using the at least one standard cell.

9. The test device of claim 1, comprising:
a random pattern generation circuit connected to the one or more processors,
wherein the one or more processors are configured to input a random input pattern output from the random pattern generation circuit to the combinational logic circuit through the plurality of flip-flops.

10. The test device of claim 9, wherein the one or more processors are configured to:
obtain a plurality of output values output from a plurality of nodes, in the combinational logic circuit, respectively connected to the plurality of flip-flops based on the random input pattern; and
determine whether an error occurs in each of the plurality of nodes, based on the plurality of output values.

11. A method of operating a test device for performing a scan test on a combinational logic circuit configured to be in electrical communication with an analog circuit, the method comprising:
inputting an input pattern to the combinational logic circuit;
obtaining a first output value output from a first output node of the combinational logic circuit;
determining whether a short current occurs in the analog circuit, by inputting the first output value into the analog circuit; and
connecting a first cell circuit corresponding to the first output value between the first output node and the analog circuit based on a determination that the short current does not occur in the analog circuit,
wherein the first cell circuit is configured to output the first output value based on a scan signal.

12. The method of claim 11, comprising:
based on the determination that the short current does not occur in the analog circuit, generating the first cell circuit comprising at least one logic element.

13. The method of claim 12, wherein the generating of the first cell circuit includes:
selecting at least one standard cell, from among standard cells stored in a standard cell library, corresponding to the at least one logic element based on the first output value, based on the determination that the short current does not occur in the analog circuit; and
generating the first cell circuit by using the at least one standard cell.

14. The method of claim 11, comprising:
inputting a random input pattern output from a random pattern generation circuit to the combinational logic circuit through a plurality of flip-flops;
obtaining a plurality of output values output from a plurality of nodes in the combinational logic circuit based on the random input pattern; and
determining whether an error occurs in each of the plurality of nodes, based on the plurality of output values.

15. The method of claim 11, comprising:
inputting different output values output from a second output node of the combinational logic circuit to the analog circuit; and
connecting a second cell circuit to the second output node based on the determination that the short current does not occur in the analog circuit by inputting the different output values to the analog circuit,
wherein the second cell circuit is configured to electrically open the second output node based on the scan signal.

16. An integrated circuit comprising:
a combinational logic circuit;
an analog circuit configured to be in electrical communication with one or more output nodes of the combinational logic circuit, wherein the one or more output nodes of the combinational logic circuit comprise a first output node; and
a test device configured to test the combinational logic circuit based on a scan signal,
wherein the test device is configured to:
input an input pattern to the combinational logic circuit;
obtain a first output value output from the first output node of the combinational logic circuit;
determine whether a short current occurs in the analog circuit, by inputting the first output value into the analog circuit; and
connect a first cell circuit corresponding to the first output value between the first output node and the analog circuit based on a determination that the short current does not occur,
wherein the first cell circuit comprises at least one logic element and is configured to output the first output value based on the scan signal.

17. The integrated circuit of claim 16, wherein based on the first output value being “0”, the first cell circuit includes:
a first inverter configured to receive the first output value from the first output node; and
a first NOR gate configured to perform a NOR operation based on an output of the first inverter and the scan signal.

18. The integrated circuit of claim 16, wherein based on the first output value being “0” and an electrical length between the combinational logic circuit and the analog circuit being greater than a predetermined threshold value, the first cell circuit includes:
a second inverter configured to receive the scan signal;
a first NAND gate configured to perform a NAND operation based on the first output value from the first output node and an output of the second inverter; and
a third inverter configured to receive an output of the first NAND gate.

19. The integrated circuit of claim 16, wherein based on the first output value being “1”, the first cell circuit includes:
a second NOR gate configured to perform a NOR operation based on the first output value from the first output node and the scan signal; and
a fourth inverter configured to receive an output of the second NOR gate.

20. The integrated circuit of claim 16, wherein the one or more output nodes of the combinational logic circuit comprise a second output node, wherein the test device is configured to:
input different output values output from the second output node of the combinational logic circuit to the analog circuit; and
connect a second cell circuit to the second output node based on the determination that the short current does not occur in the analog circuit by inputting the different output values to the analog circuit,
wherein the second cell circuit is configured to electrically open the second output node based on the scan signal.
